(19) United States
(12) Patent Application Publication
(10) Pub. No.: US 2015/0041062 A1
(43) Pub. Date: Feb. 12, 2015

(54) PLASMA PROCESSING CHAMBER WITH REMOVABLE BODY

(71) Applicant: Lam Research Corporation, Fremont, CA (US)

(72) Inventors: Michael C. KELLOGG, Oakland, CA (US); Daniel A. BROWN, Brentwood, CA (US)

(73) Assignee: Lam Research Corporation, Fremont, CA (US)

(21) Appl. No.: 13/965,036

(22) Filed: Aug. 12, 2013

(51) Int. Cl. H01J 37/32

(52) U.S. Cl. CPC H01J 37/32458; H01J 37/32009; H01J 37/32082; H01J 37/32715; H01J 37/3244; H01J 37/32513
USPC 156/345.48; 156/345.51; 118/723 R; 118/723 I

(57) ABSTRACT

An apparatus for plasma processing a wafer is provided. A bottom plate is provided. A tubular chamber wall with a wafer aperture is adjacent to the bottom plate. A bottom removable seal provides a vacuum seal between the bottom plate and the tubular chamber wall at a first end of the tubular wall. A top plate is adjacent to the tubular chamber wall. A top removable seal provides a vacuum seal between a second end of the tubular wall and the top plate. A vertical seal is provided, where a vertical movement of the tubular wall allows the vertical seal to create a seal around the wafer aperture. A bottom alignment guide aligns the tubular chamber wall with the bottom plate. A top alignment guide aligns the top plate with the tubular chamber wall. A wafer chuck is disposed between the bottom plate and the top plate.

### BACKGROUND OF THE INVENTION

### Field of the Invention

The invention relates to a chamber for plasma processing semiconductor wafers.

In forming semiconductor devices plasma processing systems are used to process semiconductor wafers.

### SUMMARY OF THE INVENTION

To achieve the foregoing and in accordance with the purpose of the present invention, an apparatus for plasma processing a wafer is provided. A bottom plate is provided. A tubular chamber wall with a wafer aperture is adjacent to the bottom plate. A bottom removable seal provides a vacuum seal between the bottom plate and the tubular chamber wall at a first end of the tubular wall. A top plate is adjacent to the tubular chamber wall. A top removable seal provides a vacuum seal between a second end of the tubular wall and the top plate. A vertical seal is provided, where a vertical movement of the tubular wall allows the vertical seal to create a seal around the wafer aperture. A bottom alignment guide aligns the tubular chamber wall with the bottom plate. A top alignment guide aligns the top plate with the tubular chamber wall. A wafer chuck is disposed between the bottom plate and the top plate.

In another manifestation of the invention, an apparatus for plasma processing a wafer is provided. A bottom plate is provided. A tubular chamber wall is adjacent to the bottom plate. A bottom removable seal provides a vacuum seal between the bottom plate and the tubular chamber wall at a first end of the tubular wall. A top plate is adjacent to the tubular chamber wall. A top removable seal provides a vacuum seal between a second end of the tubular wall and the top plate. A wafer chuck is disposed between the bottom plate and the top plate.

These and other features of the present invention will be described in more details below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is perspective view of an embodiment of the invention.

FIG. 2 is a cross-sectional view of the embodiment shown in FIG. 1.

FIG. 3 is a disassembled view of the embodiment shown in FIG. 2.

FIG. 4 is a schematic view of a plasma processing system that uses an embodiment of the invention.

FIG. 5 is an enlarged view of section 5 of the embodiment shown in FIG. 2.

FIG. 6 is an enlarged view of section 6 of the embodiment shown in FIG. 2.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

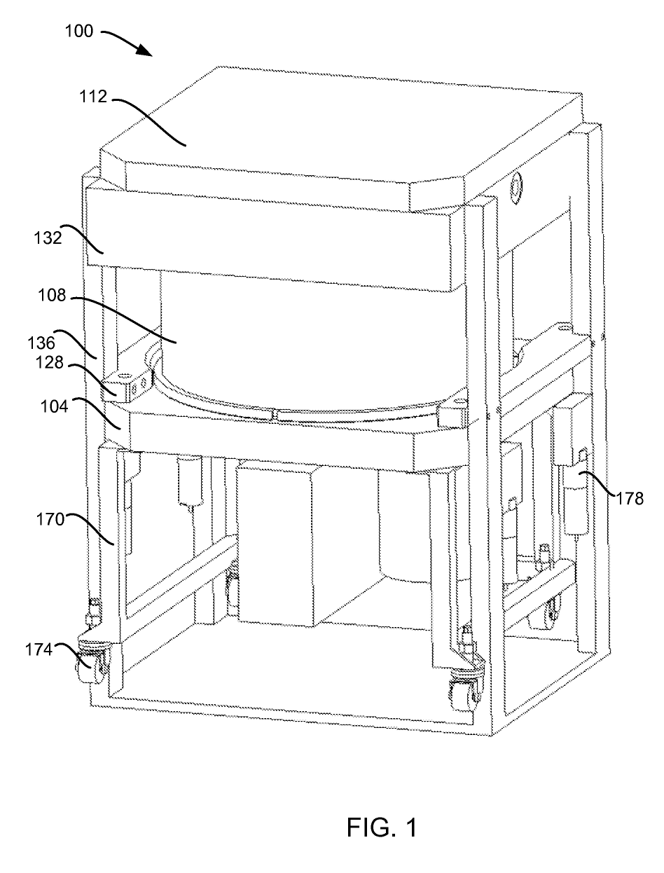

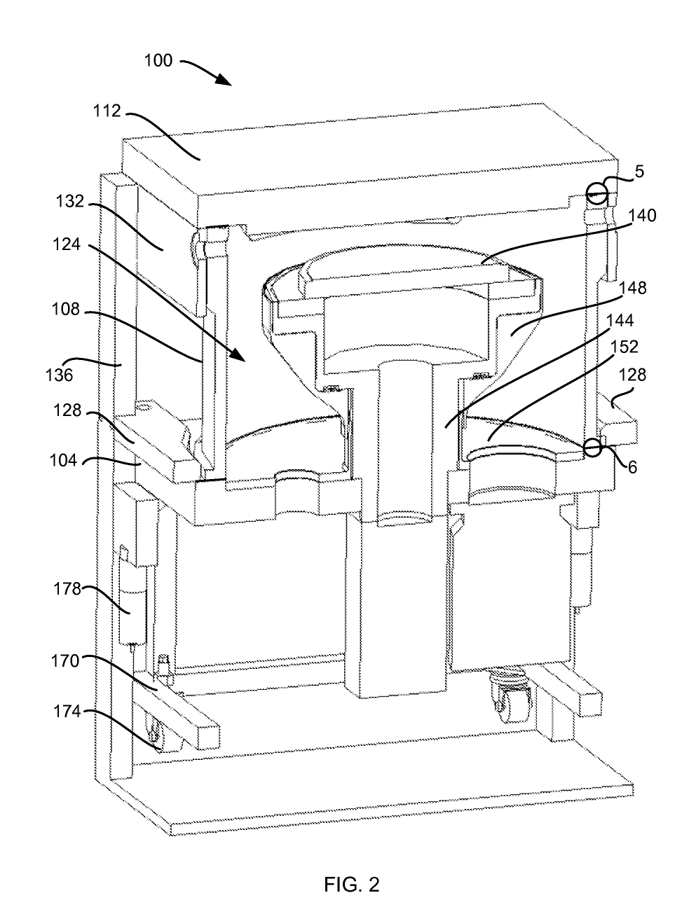

FIG. 1 is a schematic view of a chamber system 100 provided by an embodiment of the invention. The chamber system 100 comprises a bottom plate 104, a tubular chamber wall 108, and a top plate 112. In this embodiment, the tubular chamber wall 108 comprises an aluminum material. FIG. 2 is a schematic cross-sectional view of the chamber system 100. The bottom plate 104, tubular chamber wall 108, and top plate 112 define a chamber enclosure 124. Bottom rails 128 provide alignment of the tubular chamber wall 108 with respect to the bottom plate 104 in x, y, and z directions. Other types of lower alignment guides may be provided instead of the bottom rails 128 to align the tubular chamber wall 108 with respect to the bottom plate 104. An upper alignment guide 132 aligns the top of the tubular chamber wall 108. A frame 136 provides support for the bottom rails 128, the upper alignment guide 132, the bottom plate 104, and the top plate 112. The frame 136 is supported by or forms part of a cart 170 with wheels 174. The wheels 174 allow the frame 136 to be easily moved for servicing. However, during processing it may be desirable to keep the chamber system 100 stationary. To keep the chamber system 100 stationary, this embodiment uses jacks 178 to lift the cart 170 off of the wheels 174. The jacks 178 are able to lift the cart 170 up and down.

Within the chamber enclosure 124 is a wafer chuck 140 on a pedestal 144. Preferably, the wafer chuck 140 is an electrostatic chuck (ESC). A segmented bowl cover 148 is placed to surround the wafer chuck 140 and pedestal 144. A segmented bottom cover 152 is placed to cover the bottom plate 104 within the chamber enclosure 124.

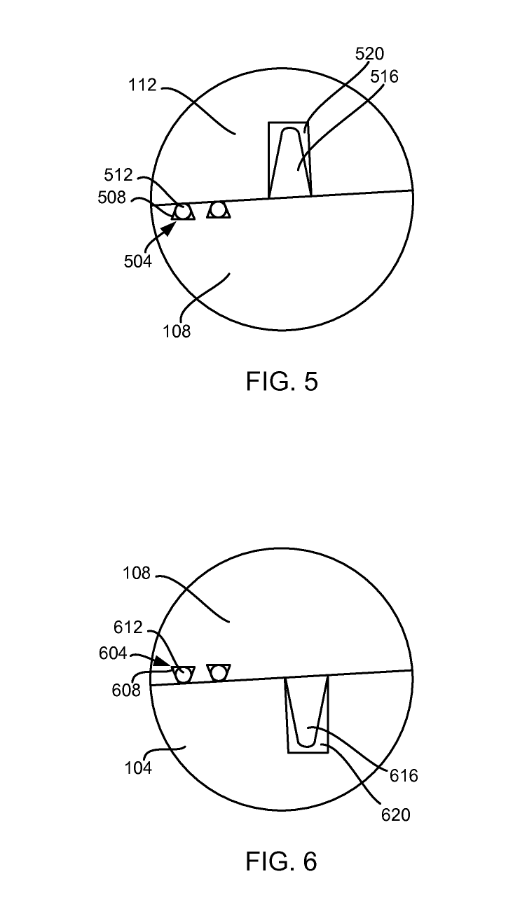

FIG. 5 is an enlarged view of section 5 in FIG. 2. FIG. 5 shows part of the top plate 112 and tubular chamber wall 108 with two upper removable seals 504, which comprise a groove 508 and an O-ring 512 within the groove 508. An alignment pin 516 extends from the top of the tubular wall 108 into an alignment aperture 520 around the alignment pin 516. Preferably, at least two alignment pins 516 extend from the top of the tubular wall 108. In other embodiments, alignment pins 516 may extend from the top plate 112 to fit into alignment apertures 520 in the tubular chamber wall 108. FIG. 6 is an enlarged view of section 6 in FIG. 2. FIG. 6 shows part of the bottom plate 104 and tubular chamber wall 108 with two lower removable seals 604, which comprise a groove 608 and an O-ring 612 within the groove 608. An alignment pin 616 extends from the bottom of the tubular wall 108 into an alignment aperture 620 around the alignment pin 616. Preferably, at least two alignment pins 616 extend from the bottom of the tubular wall 108. In other embodiments, alignment pins 616 may extend from the bottom plate 104 to fit into alignment apertures 620 in the tubular chamber wall 108. The alignment pins 516, 616 and apertures 520, 620 provide additional alignment guides.

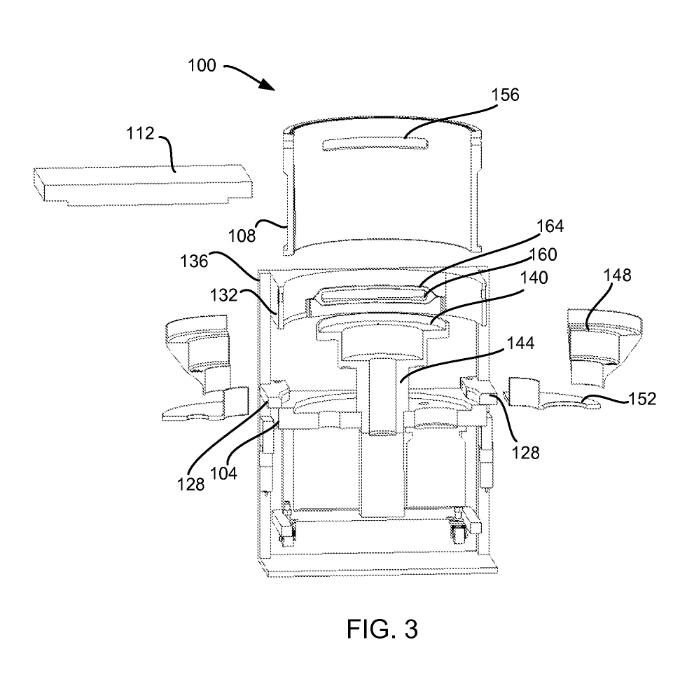

FIG. 3 is a cut away view of a disassembled chamber system 100. In disassembling the chamber system 100, the top plate 112 is removed. The tubular chamber wall 108 may be removed by vertically hoisting the tubular chamber wall 108. The segmented bowl cover 148 and segmented bottom cover 152 may be removed.

In addition, the tubular chamber wall 108 has a wafer aperture 156. The upper alignment guide 132 also has a wafer aperture 160. A vertical seal 164 is provided, where the vertical movement of the tubular chamber wall 108 with respect to the alignment guide 132 forms a seal around and between the wafer apertures 156, 160, where the wafer may be transferred into the tubular chamber wall 108 in a direction perpendicular to the vertical movement of the tubular chamber wall 108.

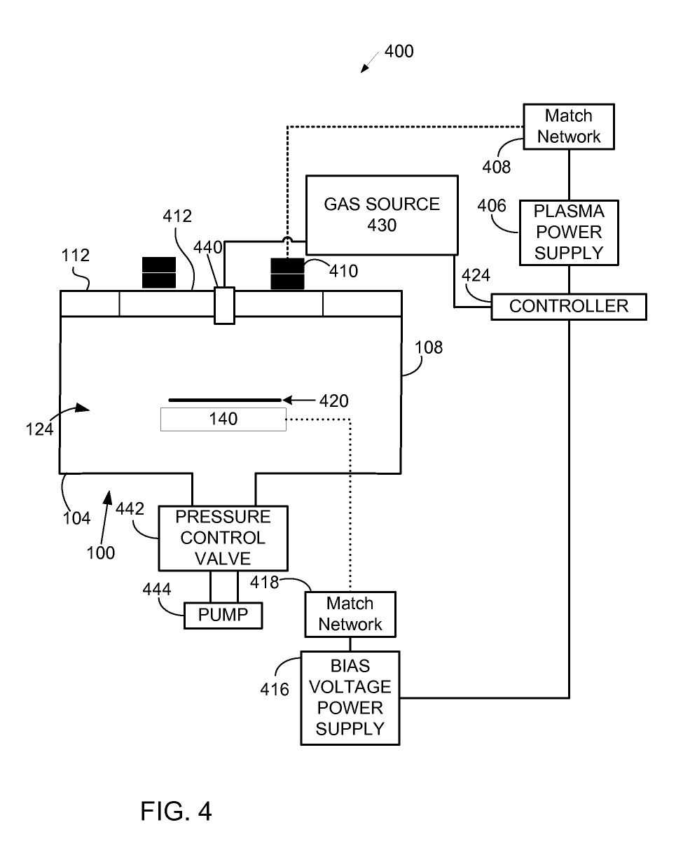

FIG. 4 is a schematic view of a plasma processing system 400, which uses the chamber system 100. In this schematic view, the top plate 112, tubular chamber wall 108, and bottom plate 104 define the chamber enclosure 124 of the chamber system 100. In addition to the chamber system 100 with the wafer chuck 140, the plasma processing system further comprises a gas source/gas supply mechanism 430 in fluid connection with the chamber enclosure 124 through a gas inlet 440. The gas inlet 440 may be located in any advantageous location in the chamber enclosure 124, and may take any form for injecting gas. Preferably, however, the gas inlet 440 may be configured to produce a “tunable” gas injection profile, which allows independent adjustment of the respective flow of the gases to multiple zones in the chamber enclosure 124. The process gases and byproducts are removed from the chamber enclosure 124 via a pressure control valve 442, which is a pressure regulator, and a pump 444, which also serves to maintain a particular pressure within the chamber enclosure 124 and also provides a gas outlet. The gas source/gas supply mechanism 430 is controlled by the controller 424.

A plasma power supply 406, tuned by a match network 408, supplies power to a TCP coil 410 located near a power window 412 formed in the top plate 112, to create a plasma in the chamber enclosure 124 by providing an inductively coupled power. The TCP coil (upper power source) 410 may be configured to produce a uniform diffusion profile within the chamber enclosure 124. For example, the TCP coil 410 may be configured to generate a toroidal power distribution. The power window 412 is provided to separate the TCP coil 410 from the chamber enclosure 124 while allowing energy to pass from the TCP coil 410 to the chamber enclosure 124. A wafer bias voltage power supply 416 tuned by a match network 418 provides power to wafer chuck 140 to set the bias voltage on a substrate 420 which is supported by the wafer chuck 140. The controller 424 sets points for the plasma power supply 406 and the wafer bias voltage power supply 416.

The plasma power supply 406 and the wafer bias voltage power supply 416 may be configured to operate at specific radio frequencies such as, for example, 13.56 MHz, 27 MHz, 2 MHz, 400 kHz, or combinations thereof. Plasma power supply 406 and wafer bias voltage power supply 416 may be appropriately sized to supply a range of powers in order to achieve desired process performance. For example, in one embodiment of the present invention, the plasma power supply 406 may supply the power in a range of 50 to 5000 Watts, and the wafer bias voltage power supply 416 may supply a bias voltage of in a range of 20 to 2000 V. In addition, the TCP coil 410 and/or the wafer chuck 140 may be comprised of two or more sub-coils or sub-electrodes, which may be powered by a single power supply or powered by multiple power supplies.

### Operation

In operation of an embodiment of the invention, a substrate is processed by first placing the substrate 420 on the wafer chuck 140 in the chamber enclosure 124. The gas source 430 provides a gas through the gas inlet 440 into the chamber enclosure 124. The plasma power supply 406, through the match network 408 and TCP coil 410 provides RF power to form the gas into a plasma. The bias voltage power supply 416 may through the match network 418 provide bias on the wafer chuck 140. A plasma process such as an etch or deposition is performed. The substrate 420 is removed and another substrate 420 may be processed. After a number of substrates are processed, the chamber system 100 is cleaned.

To clean, service, or upgrade the chamber system 100, the top plate 112 is removed. The tubular chamber wall 108 may be removed by vertically hoisting the tubular chamber wall 108. The segmented bowl cover 148 and segmented bottom cover 152 may be removed. This disassembly allows all interior surfaces of the chamber system 100 to be easily exposed for cleaning by hand. Surfaces covered by the segmented bowl cover 148 and segmented bottom cover 152 may require minimal or no cleaning If the segmented bowl cover 148 or segmented bottom cover 152 needs significant cleaning, they may be replaced with a clean segmented bowl cover 148 and segmented bottom cover 152, while the dirty segmented bowl cover 148 and segmented bottom cover 152 are cleaned and seasoned at another location.

The chamber system 100 is then reassembled, by placing the clean segmented bottom cover 152 over the bottom plate 104 and placing the clean segmented bowl cover 148 around the pedestal 144 and wafer chuck 140. The tubular chamber wall 108 is lowered onto the bottom plate 104 guided by the upper alignment guide 132 and bottom rails 128 forming the lower removable seals 604. The top plate 112 is placed on the tubular chamber wall 108 forming the upper removable seals 504

Additional equipment may be attached or moved into position. For example, the TCP coil 410 and gas inlet 440 may be placed or connected to the top plate 112.

This embodiment of the invention allows for a quicker cleaning of the chamber system 100. Parts that are more difficult to clean and season may be substituted for clean and seasoned parts and the replaced parts may be cleaned and seasoned at another location, while the chamber system 100 is used. This allows for minimal down time. The segmented bowl cover 148 and segmented bottom cover 152 make up a segmented liner.

In the prior art, chambers are more difficult to clean. If such chambers are sufficiently large, a worker may be required to climb into a chamber, which may further contaminate or otherwise damage the chamber. In addition, such a process is more difficult and slower. In addition, seasoning parts in the chamber further increases chamber down time.

While this invention has been described in terms of several preferred embodiments, there are alterations, modifications, permutations, and various substitute equivalents, which fall within the scope of this invention. It should also be noted that there are many alternative ways of implementing the methods and apparatuses of the present invention. It is therefore intended that the following appended claims be interpreted as including all such alterations, modifications, permutations, and various substitute equivalents as fall within the true spirit and scope of the present invention.

What is claimed is:

1. An apparatus for plasma processing a wafer, comprising:
a bottom plate;
a tubular chamber wall with a wafer aperture;
a bottom removable seal for providing a vacuum seal between the bottom plate and the tubular chamber wall at a first end of the tubular wall;
a top plate;
a top removable seal for providing a vacuum seal between a second end of the tubular wall and the top plate;
a vertical seal, wherein a vertical movement of the tubular wall allows the vertical seal to create a seal around the wafer aperture;
a bottom alignment guide for aligning the tubular chamber wall with the bottom plate;
a top alignment guide for aligning the top plate with the tubular chamber wall; and
a wafer chuck disposed between the bottom plate and the top plate.

2. An apparatus for plasma processing a wafer, comprising:
a bottom plate;
a tubular chamber wall;
a bottom removable seal for providing a vacuum seal between the bottom plate and the tubular chamber wall at a first end of the tubular wall;
a top plate;
a top removable seal for providing a vacuum seal between a second end of the tubular wall and the top plate; and
a wafer chuck disposed between the bottom plate and the top plate.

3. The apparatus, as recited in claim 2, wherein the tubular wall has a wafer aperture, and further comprising a vertical seal, wherein a vertical movement of the tubular wall allows the vertical seal to create a seal around the wafer aperture.

4. The apparatus, as recited in claim 3, further comprising a bottom alignment guide for aligning the tubular chamber wall with the bottom plate.

5. The apparatus, as recited in claim 4, further comprising a top alignment guide for aligning the top plate with the tubular chamber wall.

6. The apparatus, as recited in claim 5, wherein the wafer chuck is an electrostatic chuck.

7. The apparatus, as recited in claim 6, wherein a vertical movement of the tubular chamber establishes a seal for the bottom removable seal.

8. The apparatus, as recited in claim 7, further comprising at least one segmented liner disposed between the bottom plate and the top plate.

9. The apparatus, as recited in claim 8, wherein the at least one segmented liner comprise at least one segmented bottom plate cover covering the bottom plate.

10. The apparatus, as recited in claim 9, further comprising a pedestal for supporting the wafer chuck.

11. The apparatus, as recited in claim 10, wherein the at least one segmented liner further comprise at least one segmented bowl cover covering the pedestal.

12. The apparatus, as recited in claim 11, wherein the tubular chamber wall is of a material comprising aluminum.

13. The apparatus, as recited in claim 12, wherein a space between the bottom plate and top plate and within the tubular chamber wall forms a chamber enclosure, further comprising:
a gas inlet for flowing a gas into the chamber enclosure;
a gas outlet for exhausting gas from the plasma processing chamber enclosure; and
at least one electrode for providing power to the chamber enclosure for sustaining a plasma.

14. The apparatus, as recited in claim 13, further comprising:
a pressure regulator for regulating the pressure in the chamber enclosure;
at least one RF power source electrically connected to the at least one electrode;
a electrostatic chuck power source electrically connected to the electrostatic chuck; and
a gas source in fluid connection with the gas inlet.

15. The apparatus, as recited in claim 2, further comprising at least one segmented liner disposed between the bottom plate and the top plate.

16. The apparatus, as recited in claim 15, wherein the at least one segmented liner comprise at least one segmented bottom plate cover covering the bottom plate.

17. The apparatus, as recited in claim 16, further comprising a pedestal for supporting the wafer chuck.

18. The apparatus, as recited in claim 17, wherein the at least one segmented liner further comprise at least one segmented bowl cover covering the pedestal.
